(19) United States
(12) Patent Application Publication
(10) Pub. No.: US 2024/0178235 A1
(43) Pub. Date: May 30, 2024

(54) Display Substrate and Display Device

(71) Applicants: BEIJING BOE OPTOELECTRONICS TECHNOLOGY CO., LTD., Beijing (CN); BOE TECHNOLOGY GROUP CO., LTD., Beijing (CN)

(72) Inventors: Liangzhen Tang, Beijing (CN); Zhilong Duan, Beijing (CN); Xianglei Qin, Beijing (CN); Jian Wang, Beijing (CN); Yong Zhang, Beijing (CN); Ruomei Bian, Beijing (CN); Wulin Zhang, Beijing (CN); Xing Xu, Beijing (CN); Honggui Jin, Beijing (CN); Zhaohu Yu, Beijing (CN); Jinshuai Duan, Beijing (CN)

(21) Appl. No.: 17/789,464

(22) PCT Filed: Aug. 27, 2021
(86) PCT No.: PCT/CN2021/114927

§ 371 Date: Jun. 27, 2022

(51) Int. Cl. H01L 27/12

(52) U.S. Cl. CPC H01L 27/124; H01L 27/1248

(57) ABSTRACT

The present disclosure provides a display substrate and a display device. The display substrate includes a base substrate; a plurality of thin film transistors on the base substrate, each thin film transistor including a gate electrode on the base substrate; a gate insulating layer on the gate electrode; a semiconductor layer on the gate insulating layer; and a first electrode and a second electrode on the semiconductor layer; wherein the gate electrode includes an inner portion and a peripheral portion, the peripheral portion including a first portion and a second portion, wherein an orthographic projection of the second portion on the base substrate is closer to an orthographic projection of an end of the gap on the base substrate than an orthographic projection of the first portion on the base substrate, and a width of the first portion is less than a width of the second portion.

### CROSS-REFERENCE TO RELATED APPLICATIONS

The present application is a U.S. National Stage Application under 35 U.S.C. § 371 of International Patent Application No. PCT/CN2021/114927, filed on Aug. 27, 2021, the disclosure of which is incorporated by reference herein in its entirety.

### TECHNICAL FIELD

The present disclosure relates to a display substrate and a display device.

### BACKGROUND

The rapid prototyping technology is also known as 3D (three-dimensional) printing technology. In this technology, a real object or a physical model can be manufactured by means of material accumulation by a molding device. The 3D printing technology has been developed rapidly in recent years due to its advantages of significantly reducing the production cost, improving the utilization rate of the raw material and energy, performing customization as needed, and greatly saving the product fabrication time. Photopolymerization molding is to perform photosensitive curing molding on liquid photosensitive resin using near-ultraviolet light. A low-cost implementation is to use a transmissive liquid crystal display as a mask that transmits ultraviolet light to make the liquid photosensitive resin photosensitive to control 3D molding.

For 3D printing products, the client requests that the transmittance of the product is improved as much as possible. The greater transmittance indicates the more light energy transmitted through the product. Here, the light transmitted by 3D printing is for polymerization and curing, where transmittance=light energy transmitted through the product÷light energy emitted by a light source. On the one hand, the greater the transmittance is, the more the light energy transmitted is, and the shorter the resin curing and molding time will be. On the other hand, under the same optical density per unit area, the product with a greater transmittance may reduce the backlight power to save the power consumption of the product. Therefore, the client usually demands a product with a greater transmittance. Moreover, an aperture ratio of the product is directly related to the transmittance, and the larger the aperture ratio is, the greater the transmittance will be.

### SUMMARY

According to an aspect of embodiments of the present disclosure, a display substrate is provided. The display substrate comprises: a base substrate; a plurality of thin film transistors on the base substrate, each of the plurality of thin film transistors comprising: a gate electrode on the base substrate; a gate insulating layer on a side of the gate electrode away from the base substrate; a semiconductor layer on a side of the gate insulating layer away from the gate electrode; and a first electrode and a second electrode on a side of the semiconductor layer away from the gate insulating layer, the first electrode being spaced apart from the second electrode by a gap; wherein the gate electrode comprises an inner portion and a peripheral portion surrounding the inner portion, wherein an orthographic projection of the inner portion on the base substrate completely overlaps with an orthographic projection of the semiconductor layer on the base substrate, and the peripheral portion comprises a first portion and a second portion, wherein an orthographic projection of the second portion on the base substrate is closer to an orthographic projection of an end of the gap on the base substrate than an orthographic projection of the first portion on the base substrate, and a width of the first portion is less than a width of the second portion.

In some embodiments, a ratio of the width of the second portion to the width of the first portion is less than or equal to 2.06.

In some embodiments, a line width of the second electrode ranges from 3 microns to 4 microns; and a dimension of a portion of the first electrode overlapping with the semiconductor layer along an extending direction of the first electrode ranges from 5.1 microns to 7.65 microns.

In some embodiments, the display substrate further comprises a gate line connected to the gate electrode, wherein the gate line and the gate electrode are in a same layer, and a comprised angle formed by an extending direction of the first electrode and an extending direction of the gate line is an acute angle.

In some embodiments, the acute angle ranges from 30° to 60°.

In some embodiments, the display substrate further comprises an organic insulating layer on a side of the plurality of thin film transistors away from the base substrate, the organic insulating layer comprising a via hole exposing the first electrode, wherein an orthographic projection of the via hole on the base substrate at least partially overlaps with an orthographic projection of the first electrode on the base substrate.

In some embodiments, the orthographic projection of the via hole on the base substrate is located inside the orthographic projection of the first electrode on the base substrate, and located between an orthographic projection of a portion of the first electrode on the base substrate and an orthographic projection of the gate electrode on the base substrate; wherein a length of the portion of the first electrode along the extending direction of the first electrode is 2.4 microns to 3.15 microns.

In some embodiments, the first electrode comprises a third portion and a fourth portion connected to the third portion, wherein an orthographic projection of the third portion on the base substrate at least partially overlaps with an orthographic projection of the gate electrode on the base substrate, an orthographic projection of the fourth portion on the base substrate does not overlap with the orthographic projection of the gate electrode on the base substrate, and a width of the third portion in a direction perpendicular to the extending direction of the first electrode is less than a width of the fourth portion in the direction perpendicular to the extending direction of the first electrode.

In some embodiments, the width of the fourth portion in the direction perpendicular to the extending direction of the first electrode is 3.3 microns to 3.7 microns.

In some embodiments, the display substrate further comprises a pixel electrode on a side of the organic insulating layer away from the plurality of thin film transistors; wherein an orthographic projection of the gate line on the base substrate does not overlap with an orthographic projection of the pixel electrode on the base substrate, and a distance between an edge of the orthographic projection of the gate line on the base substrate and an edge of an orthographic projection of a pixel electrode adjacent to the gate line on the base substrate ranges 0.5 microns to 1.8 microns.

In some embodiments, the pixel electrode at least partially overlaps with the via hole, and the pixel electrode is electrically connected to the first electrode through the via hole.

In some embodiments, the display substrate further comprises: a data line connected to the second electrode, wherein the data line and the second electrode are in a same layer; a passivation layer on a side of the pixel electrode away from the organic insulating layer; and a common electrode on a side of the passivation layer away from the pixel electrode; wherein the common electrode comprises a plurality of sub-portions extending along the extending direction of the gate line and a plurality of strip-like electrodes between adjacent sub-portions, wherein adjacent strip-like electrodes in the plurality of strip-like electrodes are spaced apart, the plurality of strip-like electrodes are directly connected to the adjacent sub-portions, and an extending direction of the plurality of strip-like electrodes is the same as an extending direction of the data line.

In some embodiments, the display substrate further comprises a black matrix on a side of the common electrode away from the passivation layer, the black matrix comprising a first extending portion extending along the extending direction of the data line and a second extending portion extending along the extending direction of the gate line; wherein an orthographic projection of the data line on the base substrate is inside an orthographic projection of the first extending portion of the black matrix on the base substrate; a width of the data line in a direction perpendicular to the extending direction of the data line ranges from 2.6 microns to 3 microns; and a width of the first extending portion of the black matrix in the direction perpendicular to the extending direction of the data line ranges from 5 microns to 7 microns; the orthographic projection of the gate line on the base substrate is inside an orthographic projection of the second extending portion of the black matrix on the base substrate; a width of the gate line in a direction perpendicular to the extending direction of the gate line ranges from 2.5 microns to 3 microns; and a width of the second extending portion of the black matrix in the direction perpendicular to the extending direction of the gate line ranges from 6 microns to 10 microns.

In some embodiments, the orthographic projection of the second extending portion of the black matrix on the base substrate does not overlap with an orthographic projection of at least one end of at least a part of strip-like electrodes in the plurality of strip-like electrodes connected to the adjacent sub-portions on the base substrate.

According to another aspect of embodiments of the present disclosure, a display device is provided. The display device comprises the display substrate as described previously.

Other features and advantages of the present disclosure will become apparent from the following detailed description of exemplary embodiments of the present disclosure with reference to the accompanying drawings.

### BRIEF DESCRIPTION OF THE ACCOMPANYING DRAWINGS

The accompanying drawings which constitute part of the specification, illustrate the exemplary embodiments of the present disclosure, and together with the specification, serve to explain the principles of the present disclosure.

The present disclosure may be more explicitly understood from the following detailed description with reference to the accompanying drawings, in which:

FIG. 1 is a schematic top view showing a display substrate according to an embodiment of the present disclosure;

FIG. 2 is an enlarged schematic view showing a partial structure of a display substrate at a circle 101 of FIG. 1 according to an embodiment of the present disclosure;

FIG. 3 is a schematic cross-sectional view showing a structure of a display substrate taken along line A-A′ in FIG. 1 according to an embodiment of the present disclosure;

FIG. 4 is a schematic cross-sectional view showing a structure of a display substrate taken along line B-B′ in FIG. 1 according to an embodiment of the present disclosure;

FIG. 5 is a schematic top view showing a partial structure of a display substrate according to another embodiment of the present disclosure;

FIG. 6 is a schematic top view showing a partial structure of a display substrate according to another embodiment of the present disclosure;

FIG. 7 is an enlarged schematic view showing a partial structure of a display substrate at a block 102 in FIG. 1 according to an embodiment of the present disclosure;

FIG. 8 is a schematic cross-sectional view showing a structure taken along the line C-C′ in FIG. 7;

FIG. 9 is a schematic top view showing a partial structure of a display substrate according to another embodiment of the present disclosure;

FIG. 10 is an enlarged schematic view showing a partial structure of a display substrate in FIG. 1 according to an embodiment of the present disclosure.

It should be understood that the dimensions of various parts shown in the accompanying drawings are not necessarily drawn according to actual proportional relations. In addition, the same or similar reference signs are used to denote the same or similar components.

### DETAILED DESCRIPTION

Various exemplary embodiments of the present disclosure will now be described in detail in conjunction with the accompanying drawings. The description of the exemplary embodiments is merely illustrative and is in no way intended as a limitation to the present disclosure, its application or use. The present disclosure may be implemented in many different forms, which are not limited to the embodiments described herein. These embodiments are provided to make the present disclosure thorough and complete, and fully convey the scope of the present disclosure to those skilled in the art. It should be noticed that: relative arrangement of components and steps, material composition, numerical expressions, and numerical values set forth in these embodiments, unless specifically stated otherwise, should be explained as merely illustrative, and not as a limitation.

The use of the terms “first”, “second” and similar words in the present disclosure do not denote any order, quantity or importance, but are merely used to distinguish between different parts. A word such as “comprise”, “include”, or the like means that the element before the word covers the element(s) listed after the word without excluding the possibility of also covering other elements. The terms “up”, “down”, “left”, “right”, or the like are used only to represent a relative positional relationship, and the relative positional relationship may be changed correspondingly if the absolute position of the described object changes.

In the present disclosure, when it is described that a particular device is located between the first device and the second device, there may be an intermediate device between the particular device and the first device or the second device, and alternatively, there may be no intermediate device. When it is described that a particular device is connected to other devices, the particular device may be directly connected to said other devices without an intermediate device, and alternatively, may not be directly connected to said other devices but with an intermediate device.

All the terms (comprising technical and scientific terms) used in the present disclosure have the same meanings as understood by those skilled in the art of the present disclosure unless otherwise defined. It should also be understood that terms as defined in general dictionaries, unless explicitly defined herein, should be interpreted as having meanings that are consistent with their meanings in the context of the relevant art, and not to be interpreted in an idealized or extremely formalized sense.

Techniques, methods, and apparatus known to those of ordinary skill in the relevant art may not be discussed in detail, but where appropriate, these techniques, methods, and apparatuses should be considered as part of this specification.

At present, the market demands a product with a high PPI (Pixels Per Inch), so that it is necessary to improve a printing fineness of the product. PPI is a unit of image resolution, which represents the number of pixels per inch. The greater PPI value represents the display can display an image at the greater density, but the greater PPI also indicates the smaller pixel pitch. In order to achieve normal display of the product, a TFT (Thin Film Transistor) switch, a gate trace and a data trace that are opaque are required within the pixel, and in order to prevent light leakage, BM (Black Matrix) may cover the trace and TFT. Therefore, in the field of a LCD (Liquid Crystal Display) display product, the greater the PPI of the product is, the lower the pixel aperture ratio will be. For example, some products have a PPI of 538 and an aperture ratio of 43.5%, while other products have a PPI of 635, and an aperture ratio of 40% more or less. Therefore, in the related art, the aperture ratio of the display product needs to be further improved.

In view of this, an embodiment of the present disclosure provides a display substrate. By optimizing some parameters of the display substrate, the aperture ratio of the display product can be improved.

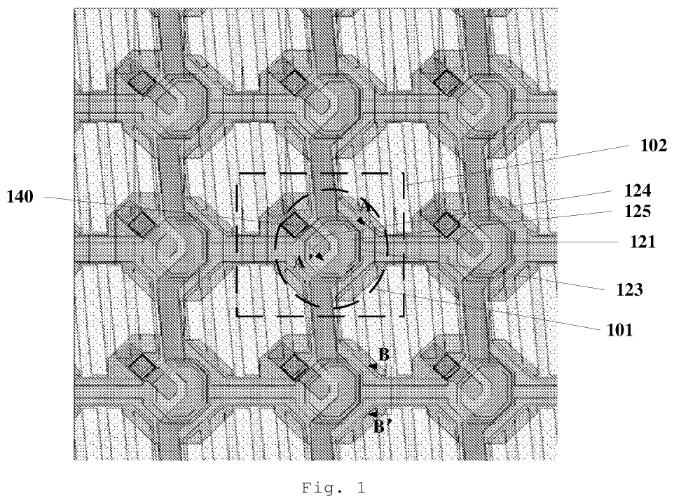

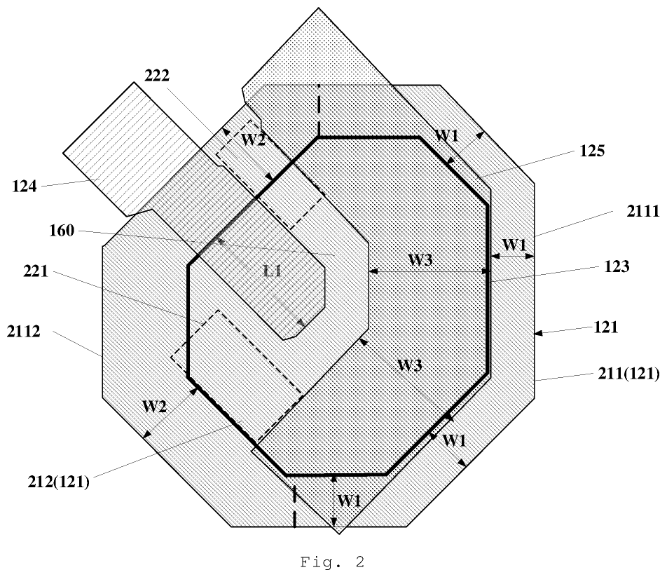

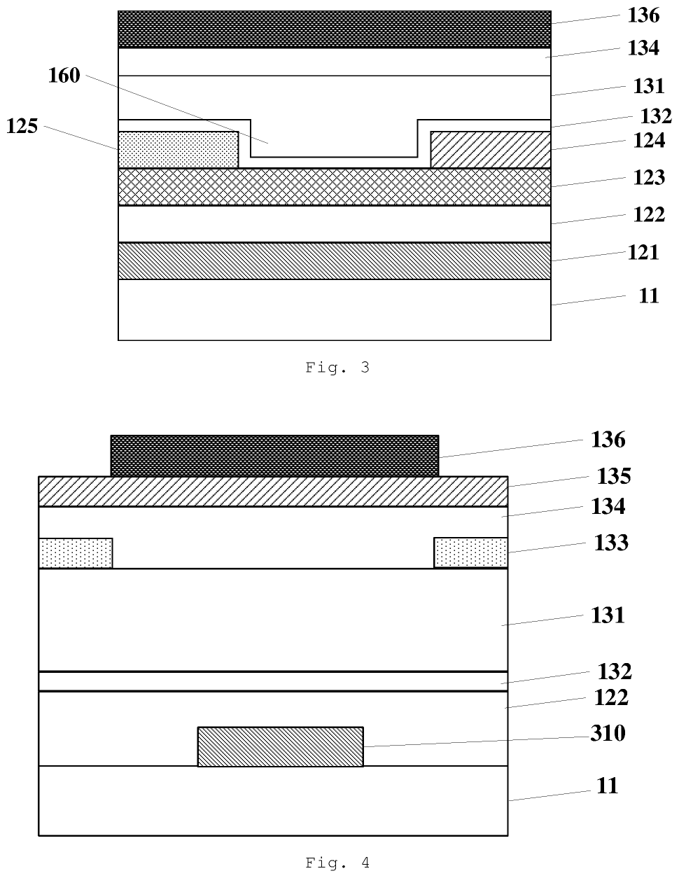

FIG. 1 is a schematic top view showing a display substrate according to an embodiment of the present disclosure. FIG. 2 is an enlarged schematic view showing a partial structure of a display substrate at a circle 101 of FIG. 1 according to an embodiment of the present disclosure. FIG. 3 is a schematic cross-sectional view showing a structure of a display substrate taken along line A-A′ in FIG. 1 according to an embodiment of the present disclosure. FIG. 4 is a schematic cross-sectional view showing a structure of a display substrate taken along line B-B′ in FIG. 1 according to an embodiment of the present disclosure. A structure of a display substrate according to an embodiment of the present disclosure will be described in detail below in conjunction with FIGS. 1 to 4.

As shown in FIGS. 3 and 4, the display substrate comprises a base substrate 11 and a plurality of thin film transistors on the base substrate 11.

As shown in FIGS. 1-4, the thin film transistor comprises a gate electrode 121 on the base substrate 11. The thin film transistor further comprises a gate insulating layer 122 on a side of the gate electrode 121 away from the base substrate 11. The gate insulating layer 122 is on the gate electrode 121. In order to facilitate showing the gate electrode 121, the gate insulating layer 122 is not shown in FIGS. 1 and 2. The thin film transistor further comprises a semiconductor layer 123 on a side of the gate insulating layer 122 away from the gate electrode 121. The semiconductor layer 123 is on the gate insulating layer 122. For example, a material of the semiconductor layer 123 comprises amorphous silicon or the like. The thin film transistor further comprises a first electrode 124 and a second electrode 125 on a side of the semiconductor layer 123 away from the gate insulating layer 122. The first electrode 124 is spaced apart from the second electrode 125 by a gap 160. For example, the first electrode 124 is a source electrode, and the second electrode 125 is a drain electrode.

As shown in FIG. 2, the gate electrode 121 comprises an inner portion 212 and a peripheral portion 211 surrounding the inner portion 212. An orthographic projection of the inner portion 212 on the base substrate 11 completely overlaps with an orthographic projection of the semiconductor layer 123 on the base substrate 11. In other words, in a case where the semiconductor layer 123 is orthographically projected onto the gate electrode 121, the gate electrode 121 is divided into two portions according to a boundary of the orthographic projection of the semiconductor layer 123 on the gate electrode 121, wherein one portion is a portion that completely overlaps with the orthographic projection of the semiconductor 123 on the gate electrode 121, which is referred to as the inner portion, and the other portion is a portion that does not overlap with the orthographic projection of the semiconductor 123 on the gate electrode 121, which is referred to as the peripheral portion.

As shown in FIG. 2, the peripheral portion 211 comprises a first portion 2111 and a second portion 2112. The peripheral portion 211 is divided into two portions 2111 and 2112. Here, an orthographic projection of the second portion 2112 on the base substrate 11 is closer to an orthographic projection of an end of the gap 160 on the base substrate 11 than an orthographic projection of the first portion 2111 on the base substrate 11. As shown in FIG. 2, the first portion 2111 is a right half of the gate electrode, and the second portion 2112 is a left half of the gate electrode. In other words, from a top view, the first portion 2111 is a portion of the peripheral portion of the gate electrode located on a drain side (for example, a right side) of the gap 160, and the second portion 2112 is a portion of the peripheral portion of the gate electrode located on a source side (for example, a left side) of the gap. For example, the first portion 2111 and the second portion 2112 are the two portions spaced apart by a dotted line in FIG. 2.

In some embodiments, as shown in FIG. 2, the gap 160 comprises channel opening areas 221 and 222 located at ends of the gap. During an operation process of the thin film transistor, a channel for conducting the first electrode 124 and the second electrode 125 can be formed in the semiconductor layer 123, and the above-described channel opening areas 221 and 222 are located at both ends of the channel, also that is, located at both ends of the gap 160.

A width W1 of the first portion 2111 is less than a width W2 of the second portion 2112. Here, the first portion and the second portion are both long strips, the width of the first portion is a dimension of the first portion in a direction perpendicular to an extending direction of the first portion, and the width of the second portion is a dimension of the second portion in a direction perpendicular to an extending direction of the second portion.

In some embodiments, a ratio of the width of the second portion 2112 to the width of the first portion 2111 is less than or equal to 2.06.

In some embodiments, the width W1 of the first portion 2111 ranges from 1.7 microns to 3 microns. For example, the width of the first portion 2111 is 2 microns.

In some embodiments, the width W2 of the second portion 2112 ranges from 2.5 microns to 3.5 microns. For example, the width of the second portion may be a width of a portion of the second portion in the vicinity of the channel opening areas 211 and 222 as shown in FIG. 2. For example, the width W2 of the second portion 2112 is 3 microns. This may prevent illumination from changing the characteristics of the thin film transistor when the display product is in use, thereby further preventing the problem of signal crosstalk resulting from increased current leakage.

So far, the display substrate according to some embodiments of the present disclosure is provided. The display substrate comprises a base substrate and a plurality of thin film transistors on the base substrate. Each thin film transistor comprises: a gate electrode on a base substrate; a gate insulating layer on a side of the gate electrode away from the base substrate; a semiconductor layer on a side of the gate insulating layer away from the gate electrode; and a first electrode and a second electrode on a side of the semiconductor layer away from the gate insulating layer. The first electrode is spaced apart from the second electrode by a gap. The gate electrode comprises an inner portion and a peripheral portion surrounding the inner portion. An orthographic projection of the inner portion on the base substrate completely overlaps with an orthographic projection of the semiconductor layer on the base substrate. The peripheral portion comprises a first portion and a second portion. An orthographic projection of the second portion on the base substrate is closer to an orthographic projection of an end of the gap on the base substrate than an orthographic projection of the first portion on the base substrate. A width of the first portion is less than a width of the second portion. In the embodiment, the width of the first portion is less than the width of the second portion, which reduces an area of the gate electrode. In conjunction with FIG. 1, it can be seen that a pixel opening (i.e., an opening corresponding to a pixel electrode (to be described later)) of the display substrate can have a greater area so as to increase an aperture ratio of the display substrate.

In some embodiments, as shown in FIG. 2, the second electrode 125 and the first electrode 124 are in a shape of a line.

In some embodiments, as shown in FIG. 2, a line width W3 of the second electrode 125 ranges from 3 microns to 4 microns. Here, the line width of the second electrode 125 is a dimension of the second electrode in a direction perpendicular to an extending direction of the second electrode. For example, the line width of the second electrode is 3.5 microns. Here, the width of the second electrode is optimized, so that the width is less than the width of the second electrode in the related art, thereby reducing a dimension of the thin film transistor and further increasing the aperture ratio of the display substrate.

In some embodiments, as shown in FIG. 2, a dimension L1 of a portion of the first electrode 124 overlapping with the semiconductor layer 123 along an extending direction of the first electrode 124 ranges from 5.1 microns to 7.65 microns. For example, the dimension L1 is 5.3 microns. This dimension range can reduce the dimension of the thin film transistor as much as possible while ensuring the lapping joint between the first electrode and the semiconductor layer, thereby increasing the aperture ratio of the display substrate.

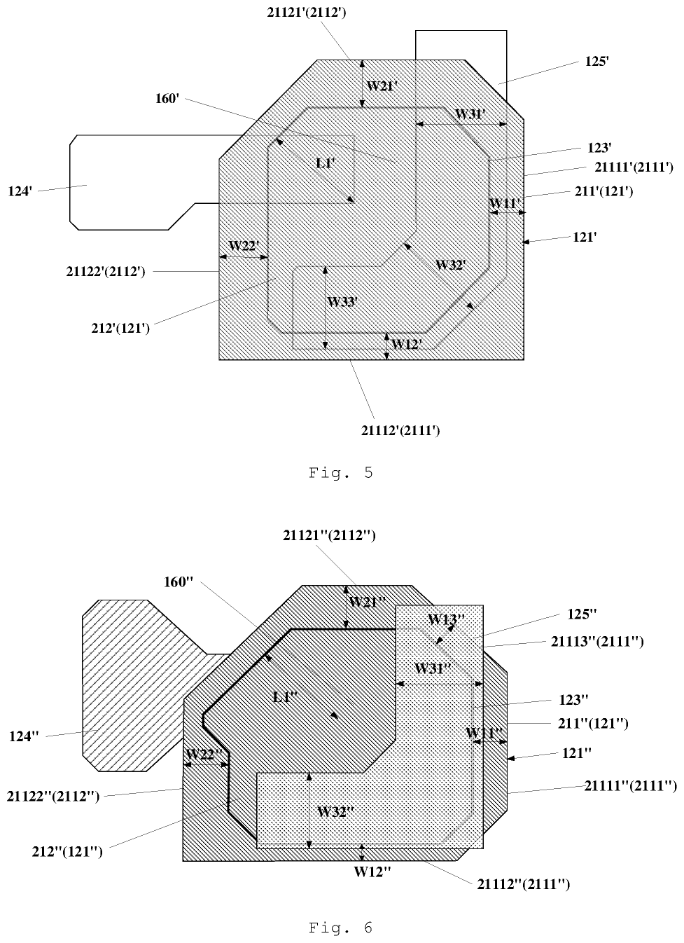

FIG. 5 is a schematic top view showing a partial structure of a display substrate according to another embodiment of the present disclosure.

Similar to FIG. 2, FIG. 5 shows a gate electrode 121′, a semiconductor layer 123′, a first electrode 124′ and a second electrode 125′. A gap 160′ is provided between the first electrode 124′ and the second electrode 125′. In order to facilitate showing the gate electrode, a gate insulating layer is not shown in FIG. 5. Similarly, as shown in FIG. 5, the gate electrode 121′ comprises an inner portion 212′ and a peripheral portion 211′ surrounding the inner portion 212′. An orthographic projection of the inner portion 212′ on a base substrate (not shown in FIG. 5) completely overlaps with an orthographic projection of the semiconductor layer 123′ on the base substrate.

As shown in FIG. 5, the peripheral portion 211′ comprises a first portion 2111′ and a second portion 2112′. Here, an orthographic projection of the second portion 2112′ on the base substrate is closer to an orthographic projection of the gap 160′ on the base substrate than an orthographic projection of the first portion 2111′ on the base substrate. The first portion 2111′ comprises a first sub-portion 21111′ and a second sub-portion 21112′, and the second portion 2112′ comprises a third sub-portion 21121′ and a fourth sub-portion 21122′.

A width of the first portion 2111′ is less than a width of the second portion 2112′. For example, a width W11′ of the first sub-portion 21111′ is 2 microns, a width W12′ of the second sub-portion 21112′ is 1.7 microns, a width W21′ of the third sub-portion 21121′ is 3 microns, and a width W22′ of the fourth sub-portion 21122′ is 3 microns. Such design can reduce the dimension of the thin film transistor, thereby increasing the aperture ratio of the display substrate.

For example, as shown in FIG. 5, a diagonal dimension L1′ of a lapping joint portion between the first electrode 124′ and the semiconductor layer 123′ is 6.25 microns. This can reduce the dimension of the thin film transistor as much as possible while ensuring the lapping joint between the first electrode and the semiconductor layer, thereby increasing the aperture ratio of the display substrate.

In some embodiments, as shown in FIG. 5, the second electrode 125′ is in a shape of a line. A line width of the second electrode 125′ ranges from 3 microns to 4 microns. The second electrode 125′ comprises a first portion extending along a direction parallel to an extending direction of a data line (to be described later), a second portion adjacent to the first portion, and a third portion extending along a direction parallel to an extending direction of a gate line (to be described later). As shown in FIG. 5, the second portion of the second electrode 125′ is a connecting portion between the first portion and the third portion of the second electrode 125′. A width W31′ of the first portion of the second electrode 125′ is a dimension of the first portion of the second electrode 125′ in a direction perpendicular to the extending direction of the data line. For example, the width W31′ of the first portion of the second electrode 125′ is 3.5 microns. A width W32′ of the second portion of the second electrode 125′ is a dimension of the second portion of the second electrode 125′ in a direction perpendicular to an extending direction of the second portion. For example, the width W32′ of the second portion of the second electrode 125′ is 3.5 microns. A width W33′ of the third portion of the second electrode 125′ is a dimension of the third portion of the second electrode 125′ in a direction perpendicular to the extending direction of the gate line. For example, the width W33′ of the third portion of the second electrode 125′ is 3.5 microns. The design of the second electrode described above can reduce the dimension of the thin film transistor, thereby increasing the aperture ratio of the display substrate.

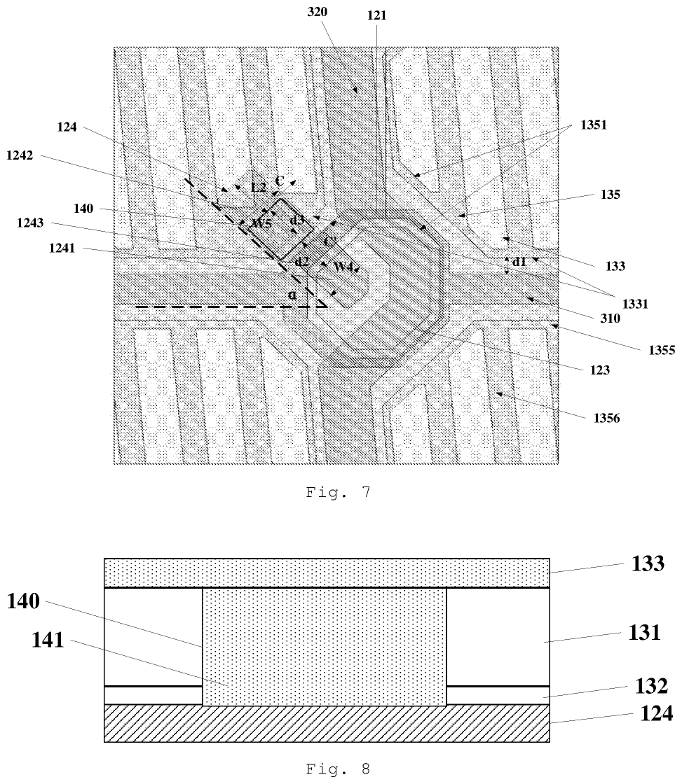

FIG. 6 is a schematic top view showing a partial structure of a display substrate according to another embodiment of the present disclosure.

Similar to FIG. 2, FIG. 6 shows a gate electrode 121″, a semiconductor layer 123″, a first electrode 124″ and a second electrode 125″. A gap 160″ is provided between the first electrode 124″ and the second electrode 125″. In order to facilitate showing the gate electrode, a gate insulating layer is not shown in FIG. 6. Similarly, as shown in FIG. 6, the gate electrode 121″ comprises an inner portion 212″ and a peripheral portion 211″ surrounding the inner portion 212″. An orthographic projection of the inner portion 212″ on a base substrate (not shown in FIG. 6) completely overlaps with an orthographic projection of the semiconductor layer 123″ on the base substrate.

As shown in FIG. 6, the peripheral portion 211″ comprises a first portion 2111″ and a second portion 2112″. Here, an orthographic projection of the second portion 2112″ on the base substrate is closer to an orthographic projection of the gap 160″ on the base substrate than an orthographic projection of the first portion 2111″ on the base substrate. The first portion 2111″ comprises a first sub-portion 21111″, a second sub-portion 21112″ and a third sub-portion 21113″, wherein the first sub-portion 21111″ is between the second sub-portion 21112″ and the third sub-portion 21113″. The second section 2112″ comprises a fourth sub-portion 21121″ and a fifth sub-portion 21122″.

A width of the first portion 2111″ is less than a width of the second portion 2112″. For example, a width W11″ of the first sub-portion 21111″ is 2 microns, a width W12″ of the second sub-portion 21112″ is 1.7 microns, a width W13″ of the third sub-portion 21113″ is 1.75 microns, a width W21″ of the fifth sub-portion 21121″ is 3 microns, and a width W22″ of the fifth sub-portion 21122″ is 3 microns. Such design can reduce the dimension of the thin film transistor, thereby increasing the aperture ratio of the display substrate.

For example, as shown in FIG. 6, a diagonal dimension L1″ of a lapping joint portion between the first electrode 124″ and the semiconductor layer 123″ is 6.2 microns. This can reduce the dimension of the thin film transistor as much as possible while ensuring the lapping joint between the first electrode and the semiconductor layer, thereby increasing the aperture ratio of the display substrate is increased.

In some embodiments, as shown in FIG. 6, the second electrode 125″ is in a shape of a line. A line width of the second electrode 125″ ranges from 3 microns to 4 microns. For example, the second electrode 125″ comprises a first portion extending along a direction parallel to an extending direction of a data line (to be described later) and a second portion extending along a direction parallel to an extending direction of a gate line (to be described later). A width W31″ of the first portion of the second electrode 125″ is a dimension of the first portion of the second electrode in a direction perpendicular to the extending direction of the data line. For example, the width W31″ of the first portion of the second electrode 125″ is 3.5 microns. A width W32″ of the second portion of the second electrode 125″ is a dimension of the second portion of the second electrode in a direction perpendicular to the extending direction of the gate line. For example, the width W32″ of the second portion of the second electrode 125″ is 3.5 microns. The design of the second electrode described above can reduce the dimension of the thin film transistor, thereby increasing the aperture ratio of the display substrate.

FIG. 7 is an enlarged schematic view showing a partial structure of a display substrate at a block 102 in FIG. 1 according to an embodiment of the present disclosure. It should be noted that, a black matrix is not shown in FIG. 7.

As shown in FIG. 7, the display substrate further comprises a gate line 310 connected to the gate electrode 121. The gate line 310 and the gate electrode 121 are in a same layer. For example, the gate line 310 and the gate electrode 121 are both on the base substrate 11. For example, a material of the gate line is the same as a material of the gate electrode. The gate line and the gate electrode can be formed through the same patterning process. As described above, the first electrode 124 is in the shape of a line. A comprised angle α formed by an extending direction of the first electrode 124 and an extending direction of the gate line 310 is an acute angle. In some embodiments, the acute angle α ranges from 30° to 60°. For example, the acute angle α is 45°. Here, by designing the comprised angle formed by the extending direction of the first electrode 124 and the extending direction of the gate line 310 to be an acute angle, that is, designing the first electrode so as not to be arranged horizontally or vertically, it is possible to facilitate a lapping joint between the first electrode and a via hole (to be described later) of an organic insulating layer while reducing the dimension of the thin film transistor, so as not to affect the performance of the display substrate.

Returning to FIGS. 3 and 4, in some embodiments, the display substrate further comprises an organic insulating layer 131 on a side of the plurality of thin film transistors away from the base substrate 11. For example, a material of the organic insulating layer comprises resin or the like. The organic insulating layer can reduce a load effect of the display panel. The organic insulating layer 131 comprises a via hole 140 (as shown in FIG. 7) exposing the first electrode 124. For the ease of illustration, FIG. 7 shows a contour of the via hole 140 rather than the organic insulating layer. As shown in FIG. 7, an orthographic projection of the via hole 140 on the base substrate 11 at least partially overlaps with an orthographic projection of the first electrode 124 on the base substrate 11. The via hole can cause a pixel electrode to be described later to be electrically connected with the first electrode 124.

In some embodiments, as shown in FIG. 7, the orthographic projection of the via hole 140 on the base substrate 11 is located inside the orthographic projection of the first electrode 124 on the base substrate 11, and located between an orthographic projection of a portion of the first electrode 124 on the base substrate 11 and an orthographic projection of the gate electrode 121 on the base substrate 11. Here, a length L2 of the portion of the first electrode 124 along the extending direction of the first electrode 124 is 2.4 microns to 3.15 microns. Here, the length L2 is a distance from an end of the portion of the first electrode 124 away from the via hole 140 to an edge of the portion of the first electrode 124 closest to the via hole 140. In this way, it is possible to ensure that the orthographic projection of the first electrode completely wraps the orthographic projection of the via hole, so as to allow an adequate lapping joint between the first electrode and the via hole.

It should be noted that, during a process of manufacturing the display substrate, in order to make the length L2 of the portion of the first electrode 124 satisfy 2.4 microns to 3.15 microns, a corresponding dimension of a mask used may be slightly larger, for example, it may be 4.75 microns. In this way, it is possible to ensure that there is still an adequate lapping joint between the first electrode and the via hole in the case of considering process alignment and line width fluctuation.

In some embodiments, the above-described via hole 140 may be arranged in parallel with the first electrodes 124 (an extending direction of the orthographic projection of the via hole 140 is parallel to an extending direction of the orthographic projection of the first electrodes 124), so as to reduce an area of the first electrode as much as possible.

In some embodiments, as shown in FIG. 7, the first electrode 124 comprises a third portion 1241 and a fourth portion 1242 connected to the third portion 1241. An orthographic projection of the third portion 1241 on the base substrate 11 at least partially overlaps with an orthographic projection of the gate electrode 121 on the base substrate 11. An orthographic projection of the fourth portion 1242 on the base substrate 11 does not overlap with the orthographic projection of the gate electrode 121 on the base substrate 11. A width W4 of the third portion 1241 in a direction perpendicular to the extending direction of the first electrode 124 is less than a width W5 of the fourth portion 1242 in the direction perpendicular to the extending direction of the first electrode 124. This can reduce a facing area between the first electrode and the gate electrode, thereby reducing a parasitic capacitance formed by the first electrode and the gate electrode.

In some embodiments, the width W5 of the fourth portion 1242 in the direction perpendicular to the extending direction of the first electrode 124 is 3.3 microns to 3.7 microns. In this way, it is possible to allow a relatively large lapping joint area between the via hole 140 and the first electrode 124.

In some embodiments, the first electrode 124 further comprises a connecting portion 1243 between the third portion 1241 and the fourth portion 1242. A width of the connecting portion 1243 gradually widens along a direction from the third portion 1241 to the fourth portion 1242. This allows the first electrode to gradually transition from its third portion to its fourth portion. The width of the connection portion 1243 refers to a dimension of the connection portion along the direction perpendicular to the extending direction of the first electrode 124.

In addition, as shown in FIG. 4, an orthographic projection of a portion (i.e., a portion close to the third portion 1241) of the connecting portion 1243 on the base substrate overlaps with the orthographic projection of the gate electrode 121 on the base substrate, and an orthographic projection of another portion (i.e., a portion close to the fourth portion 1242) of the connecting portion 1243 on the base substrate does not overlap with the orthographic projection of the gate electrode 121 on the base substrate.

In some embodiments, as shown in FIG. 3, the display substrate may further comprise a buffer layer 132 covering the semiconductor layer 123, the first electrode 124 and the second electrode 125. The organic insulating layer 131 is on the buffer layer 132. That is, the buffer layer 132 is between the organic insulating layer 131 and the semiconductor layer 123, the first electrode 124 and the second electrode 125. For example, a material of the buffer layer 132 comprises an inorganic insulating material such as silicon oxide or silicon nitride.

In some embodiments, as shown in FIGS. 4 and 7, the display substrate further comprises a pixel electrode 133 on a side of the organic insulating layer 131 away from the plurality of thin film transistors. FIG. 7 shows an edge 1331 of the pixel electrode 133. As shown in FIG. 7, an orthographic projection of the gate line 310 on the base substrate 11 does not overlap with an orthographic projection of the pixel electrode 133 on the base substrate 11, and a distance d1 between an edge of the orthographic projection of the gate line 310 on the base substrate 11 and an edge of an orthographic projection of a pixel electrode 133 adjacent to the gate line on the base substrate 11 ranges from 0.5 microns to 1.8 microns. This can make a lapping joint area between the pixel electrode and the via hole 140 relatively large.

For example, in the case where the above-described distance d1 is changed from 3 microns in the related art to 1.8 microns, a lapping joint distance between the pixel electrode and the via hole may be changed from 2.75 microns to 3.95 microns, thereby increasing a lapping joint area between the pixel electrode and the via hole and avoiding the problem of placing the via hole inside a pixel to occupy a pixel opening area in order to ensure that the lapping joint area between the pixel electrode and the via hole is large enough.

In some embodiments, a distance between the gate line and one adjacent pixel electrode is equal to a distance between the gate line and another adjacent pixel electrode. From the perspective of a top view, the one adjacent pixel electrode and the anther adjacent pixel electrode are located on both sides of the gate line respectively.

In the above-described embodiments, as shown in FIG. 7, the lapping joint distance between the pixel electrode and the via hole is a dimension d3 of an overlapping portion of the orthographic projection of the pixel electrode 133 on the base substrate and the orthographic projection of the via hole 140 on the base substrate. The dimension is a dimension of the overlapping portion along the extending direction of the first electrode 124. In some embodiments, the dimension d3 is 3.3 microns to 5 microns. That is, the lapping joint distance between the pixel electrode and the via hole is 3.3 microns to 5.0 microns, for example, 3.95 microns. This can make a lapping joint area between the pixel electrode and the via hole relatively large.

In some embodiments, a distance d2 between the orthographic projection of the via hole 140 on the base substrate and the orthographic projection of the semiconductor layer 123 on the base substrate is 3.1 microns to 4 microns. In this way, an area of the semiconductor layer is minimized, thereby achieving the purpose of keeping the via hole as far away from the interior of the pixel as possible. Since the via hole is placed at a position away from a boundary of the semiconductor layer, which can avoid affecting the characteristics of the thin film transistor, reducing the area of the semiconductor layer can keep the via hole as far away as possible from the interior of the pixel, which is beneficial to increase the aperture ratio of the display substrate.

In addition, in the foregoing embodiments, the area of the gate electrode is reduced by making the width of the first portion of the peripheral portion of the gate electrode less than the width of the second portion. This can correspondingly increase the area of the pixel electrode, so that the boundary of the pixel electrode expands to the periphery of the pixel as much as possible to ensure that the lapping joint area between the via hole of the organic insulating layer and the pixel electrode is as large as possible, and avoid the problem that the via hole of the organic insulating layer is moved toward the interior of the pixel so that the aperture ratio is affected in order to ensure that the lapping joint area between the pixel electrode and the via hole is as large as possible.

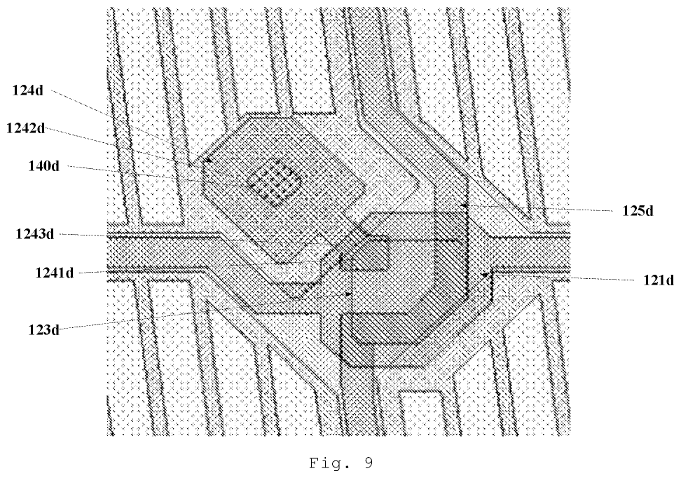

FIG. 8 is a schematic cross-sectional view showing a structure taken along the line C-C′ in FIG. 7. It should be noted that, for ease of illustration, FIG. 8 only shows the first electrode 124, the buffer layer 132, the organic insulating layer 131, the via hole 140 and the pixel electrode 133. The via hole 140 comprises a conductive material layer 141 (for example, metal). For example, a material of the conductive material layer is the same as a material of the pixel electrode.

As shown in FIGS. 7 and 8, the pixel electrode 133 at least partially overlaps with the via hole 140, and the pixel electrode 133 is electrically connected to the first electrode 124 through the via hole 140 (for example, the conductive material layer 141 in the via hole 140).

In some embodiments, as shown in FIG. 7, the display substrate further comprises a data line 320 connected to the second electrode 125. The data line 320 and the second electrode 125 are in a same layer. For example, a material of the data line is the same as a material of the second electrode 125. The data line 320 and the second electrode 125 can be formed through the same patterning process.

In some embodiments, as shown in FIGS. 4 and 7, the display substrate further comprises a passivation layer 134 on a side of the pixel electrode 133 away from the organic insulating layer 131. For example, a material of the passivation layer 134 comprises an inorganic insulating material such as silicon oxide or silicon nitride.

In some embodiments, as shown in FIGS. 4 and 7, the display substrate further comprises a common electrode 135 on a side of the passivation layer 134 away from the pixel electrode 133. FIG. 7 shows an edge 1351 of the common electrode 135.

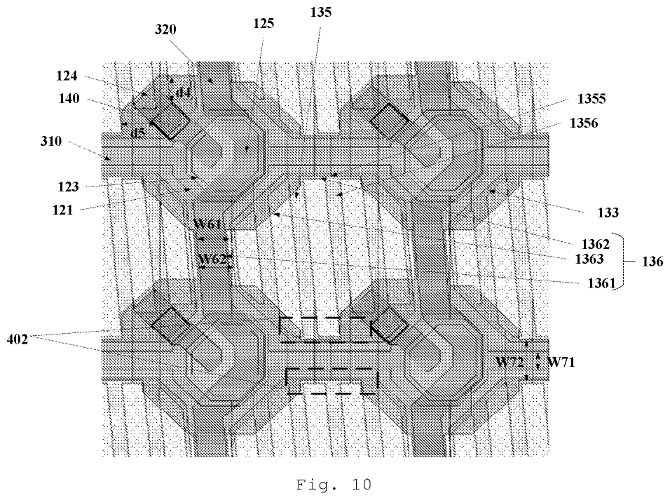

FIG. 9 is a schematic top view showing a partial structure of a display substrate according to another embodiment of the present disclosure.

FIG. 9 shows a gate electrode 121d, a semiconductor layer 123d, a first electrode 124d, a second electrode 125d, and a via hole 140d. As shown in FIG. 9, the first electrode 124d comprises a first sub-portion 1241d, a second sub-portion 1242d and a third sub-portion 1243d. An orthographic projection of the first sub-portion 1241d of the first electrode 124d on a base substrate overlaps with an orthographic projection of the gate electrode 121d on the base substrate. An orthographic projection of the second sub-portion 1242d of the first electrode 124d on the base substrate does not overlap with the orthographic projection of the gate electrode 121d on the base substrate. The third sub-portion 1243d is connected between the first sub-portion 1241d and the second sub-portion 1242d. As shown in FIG. 9, a width of the third sub-portion 1243d in a direction perpendicular to an extending direction of the first electrode 124d is less than a width of the second sub-portion 1242d in the direction perpendicular to the extending direction of the first electrode 124d, and a width of the first sub-portion 1241d in the direction perpendicular to the extending direction of the first electrode 124d is less than the width of the second sub-portion 1242d in the direction perpendicular to the extending direction of the first electrode 124d. This can not only ensure that a lapping joint area between the second sub-portion 1242d of the first electrode 124d and the via hole 140d is relatively large, but also can make a parasitic capacitance formed by the first sub-portion 1241d of the first electrode 124d and the gate electrode 121d relatively small, thereby improving the performance of the display substrate.

FIG. 10 is an enlarged schematic view showing a partial structure of a display substrate in FIG. 1 according to an embodiment of the present disclosure.

As shown in FIGS. 7 and 10, the common electrode 135 comprises a plurality of sub-portions 1355 extending along the extending direction of the gate line and a plurality of strip-like electrodes 1356 between adjacent sub-portions 1355. Adjacent strip-like electrodes in the plurality of strip-like electrodes 1356 are spaced apart. The plurality of strip-like electrodes 1356 are directly connected to the adjacent sub-portions 1355, and an extending direction of the plurality of strip-like electrodes 1356 is the same as an extending direction of the data line 320. That is, the strip-like electrode has its corner portions removed.

In some embodiments, the above-described common electrode 135 further comprises an inclined portion between the strip-like electrode and the sub-portion extending along the extending direction of the gate line.

In some embodiments, as shown in FIGS. 4 and 10, the display substrate further comprises a black matrix 136 on a side of the common electrode 135 away from the passivation layer 134. The black matrix 136 comprises a first extending portion 1361 extending along the extending direction of the data line 320 and a second extending portion 1362 extending along the extending direction of the gate line 310. The black matrix 136 may further comprise an intersecting portion 1363 connecting the first extending portion 1361 and the second extending portion 1362.

As shown in FIG. 10, an orthographic projection of the data line 320 on the base substrate is inside an orthographic projection of the first extending portion 1361 of the black matrix 136 on the base substrate.

In some embodiments, a width W61 of the data line 320 in a direction perpendicular to the extending direction of the data line ranges from 2.6 microns to 3 microns. A width W62 of the first extending portion 1361 of the black matrix 136 in the direction perpendicular to the extending direction of the data line ranges from 5 microns to 7 microns. For example, the width of the first extending portion 1361 is 6 microns. In this way, it is possible to reduce a blocking area of the black matrix while ensuring that the black matrix completely blocks the data line, thereby increasing the aperture ratio of the display substrate.

As shown in FIG. 10, the orthographic projection of the gate line 310 on the base substrate is inside an orthographic projection of the second extending portion 1362 of the black matrix 136 on the base substrate.

In some embodiments, a width W71 of the gate line 310 in a direction perpendicular to the extending direction of the gate line ranges from 2.5 microns to 3 microns. A width W72 of the second extending portion 1362 of the black matrix 136 in the direction perpendicular to the extending direction of the gate line ranges from 6 microns to 10 microns. For example, the width of the second extending portion 1362 is 8 microns. In this way, it is possible to reduce a blocking area of the black matrix while ensuring that the black matrix can completely block the gate line, thereby increasing the aperture ratio of the display substrate.

In some embodiments, the orthographic projection of the second extending portion 1362 of the black matrix 136 on the base substrate does not overlap with an orthographic projection of at least one end of at least a part of strip-like electrodes in the plurality of strip-like electrodes 1356 connected to the adjacent sub-portions on the base substrate, as shown at block 402 in FIG. 10. For example, as shown in FIG. 10, an orthographic projection of an upper end of one strip-like electrode may overlap with the orthographic projection of the second extending portion 1362 of the black matrix 136, and an orthographic projection of a lower end of the one strip-like electrode may not overlap with the orthographic projection of the second extending portion 1362 of the black matrix 136. For another example, an orthographic projection of an upper end of another strip-like electrode may not overlap with the orthographic projection of the second extending portion 1362 of the black matrix 136, and an orthographic projection of a lower end of the another strip-like electrode may overlap with the orthographic projection of the second extending portion 1362 of the black matrix 136. As previously described, the strip-like electrode has its corner portion removed. In this embodiment, by removing the corner portion of the strip-like electrode in the related art, and making the orthographic projection of the second extending portion of the black matrix not overlap with the orthographic projection of at least one end of some strip-like electrodes, it is possible to reduce the width W72 of the second extending portion of the black matrix in the direction perpendicular to the extending direction of the gate line while ensuring the light efficiency design of the display substrate, thereby increasing the aperture ratio of the display substrate.

In some embodiments, as shown in FIG. 10, distances d4 and d5 between the edge of the orthographic projection of the via hole 140 on the base substrate and the edge of the orthographic projection of the black matrix on the base substrate are both 5.25 microns to 6 microns. For example, the distances d4 and d5 are 5.5 microns.

In the display substrate of the embodiments of the present disclosure, by optimizing parameters of the thin film transistors such as various line widths, other widths, distance and/or length, the dimension of the thin film transistor of the product is minimized while not affecting the characteristics of the thin film transistor, and the dimension parameters related to the via hole are optimized while ensuring that a lapping joint area between the via hole of the organic insulating layer and other structural layers is relatively large, so that the via hole is away from the interior of the pixel as much as possible, thereby improving the aperture ratio of the pixel. In addition, the line width of the black matrix is optimized to further improve the aperture ratio. In this way, the aperture ratio of the display product can be improved in a maximized manner. For example, by using the design of the thin film transistor and the position of the via hole in the above-described solution of the present disclosure, the aperture ratio of the display substrate can be improved from 50% in the related art to 57.4%.

In some embodiments of the present disclosure, a display device is also provided. The display device comprises the display substrate as described previously. For example, the display device may be any product or member having a display function, such as a display panel, a mobile phone, a tablet computer, a television, a display, a notebook computer, a digital photo frame, a navigator, or the like.

Hereto, various embodiments of the present disclosure have been described in detail. Some details well known in the art are not described in order to avoid obscuring the concept of the present disclosure. According to the above description, those skilled in the art would fully understand how to implement the technical solutions disclosed here.

Although some specific embodiments of the present disclosure have been described in detail by way of examples, those skilled in the art should understand that the above examples are only for the purpose of illustration but not for limiting the scope of the present disclosure. It should be understood by those skilled in the art that modifications to the above embodiments or equivalently substitution of part of the technical features may be made without departing from the scope and spirit of the present disclosure. The scope of the present disclosure is defined by the appended claims.

1. A display substrate, comprising:
a base substrate;
a plurality of thin film transistors on the base substrate, each of the plurality of thin film transistors comprising:
a gate electrode on the base substrate;
a gate insulating layer on a side of the gate electrode away from the base substrate;
a semiconductor layer on a side of the gate insulating layer away from the gate electrode; and
a first electrode and a second electrode on a side of the semiconductor layer away from the gate insulating layer, the first electrode being spaced apart from the second electrode by a gap;
wherein the gate electrode comprises an inner portion and a peripheral portion surrounding the inner portion, wherein an orthographic projection of the inner portion on the base substrate completely overlaps with an orthographic projection of the semiconductor layer on the base substrate, and the peripheral portion comprises a first portion and a second portion, wherein an orthographic projection of the second portion on the base substrate is closer to an orthographic projection of an end of the gap on the base substrate than an orthographic projection of the first portion on the base substrate, and a width of the first portion is less than a width of the second portion.

2. The display substrate according to claim 1, wherein a ratio of the width of the second portion to the width of the first portion is less than or equal to 2.06.

3. The display substrate according to claim 1, wherein:
a line width of the second electrode ranges from 3 microns to 4 microns; and
a dimension of a portion of the first electrode overlapping with the semiconductor layer along an extending direction of the first electrode ranges from 5.1 microns to 7.65 microns.

4. The display substrate according to claim 1, further comprising:
a gate line connected to the gate electrode, wherein the gate line and the gate electrode are in a same layer, and a comprised angle formed by an extending direction of the first electrode and an extending direction of the gate line is an acute angle.

5. The display substrate according to claim 4, wherein the acute angle ranges from 300 to 60°.

6. The display substrate according to claim 4, further comprising:
an organic insulating layer on a side of the plurality of thin film transistors away from the base substrate, the organic insulating layer comprising a via hole exposing the first electrode, wherein an orthographic projection of the via hole on the base substrate at least partially overlaps with an orthographic projection of the first electrode on the base substrate.

7. The display substrate according to claim 6, wherein:
the orthographic projection of the via hole on the base substrate is located inside the orthographic projection of the first electrode on the base substrate, and located between an orthographic projection of a portion of the first electrode on the base substrate and an orthographic projection of the gate electrode on the base substrate;
wherein a length of the portion of the first electrode along the extending direction of the first electrode is 2.4 microns to 3.15 microns.

8. The display substrate according to claim 6, wherein the first electrode comprises a third portion and a fourth portion connected to the third portion, wherein an orthographic projection of the third portion on the base substrate at least partially overlaps with an orthographic projection of the gate electrode on the base substrate, an orthographic projection of the fourth portion on the base substrate does not overlap with the orthographic projection of the gate electrode on the base substrate, and a width of the third portion in a direction perpendicular to the extending direction of the first electrode is less than a width of the fourth portion in the direction perpendicular to the extending direction of the first electrode.

9. The display substrate according to claim 8, wherein the width of the fourth portion in the direction perpendicular to the extending direction of the first electrode is 3.3 microns to 3.7 microns.

10. The display substrate according to claim 6, further comprising:
a pixel electrode on a side of the organic insulating layer away from the plurality of thin film transistors;
wherein an orthographic projection of the gate line on the base substrate does not overlap with an orthographic projection of the pixel electrode on the base substrate, and a distance between an edge of the orthographic projection of the gate line on the base substrate and an edge of an orthographic projection of a pixel electrode adjacent to the gate line on the base substrate ranges 0.5 microns to 1.8 microns.

11. The display substrate according to claim 10, wherein the pixel electrode at least partially overlaps with the via hole, and the pixel electrode is electrically connected to the first electrode through the via hole.

12. The display substrate according to claim 10, further comprising:
a data line connected to the second electrode, wherein the data line and the second electrode are in a same layer;
a passivation layer on a side of the pixel electrode away from the organic insulating layer; and
a common electrode on a side of the passivation layer away from the pixel electrode;
wherein the common electrode comprises a plurality of sub-portions extending along the extending direction of the gate line and a plurality of strip-like electrodes between adjacent sub-portions, wherein adjacent strip-like electrodes in the plurality of strip-like electrodes are spaced apart, the plurality of strip-like electrodes are directly connected to the adjacent sub-portions, and an extending direction of the plurality of strip-like electrodes is the same as an extending direction of the data line.

13. The display substrate according to claim 12, further comprising:
a black matrix on a side of the common electrode away from the passivation layer, the black matrix comprising a first extending portion extending along the extending direction of the data line and a second extending portion extending along the extending direction of the gate line;
wherein an orthographic projection of the data line on the base substrate is inside an orthographic projection of the first extending portion of the black matrix on the base substrate; a width of the data line in a direction perpendicular to the extending direction of the data line ranges from 2.6 microns to 3 microns; and a width of the first extending portion of the black matrix in the direction perpendicular to the extending direction of the data line ranges from 5 microns to 7 microns;
the orthographic projection of the gate line on the base substrate is inside an orthographic projection of the second extending portion of the black matrix on the base substrate; a width of the gate line in a direction perpendicular to the extending direction of the gate line ranges from 2.5 microns to 3 microns; and a width of the second extending portion of the black matrix in the direction perpendicular to the extending direction of the gate line ranges from 6 microns to 10 microns.

14. The display substrate according to claim 12, wherein the orthographic projection of the second extending portion of the black matrix on the base substrate does not overlap with an orthographic projection of at least one end of at least a part of strip-like electrodes in the plurality of strip-like electrodes connected to the adjacent sub-portions on the base substrate.

15. A display device, comprising: the display substrate according to claim 1.
